(19) United States
(12) Patent Application Publication
(10) Pub. No.: US 2010/0073021 A1
(43) Pub. Date: Mar. 25, 2010

(54) ELECTRICAL CONTACT PROBE

(75) Inventors: Cheng-Lien Chiang, TAIPEI (TW); Sheng-Chang Huang, CHUNG-HO CITY (TW)

Correspondence Address: PAI PATENT & TRADEMARK LAW FIRM, 1001 FOURTH AVENUE, SUITE 3200, SEATTLE, WA, 98154, US

(73) Assignees: NICHEPAC TECHNOLOGY INC., JHONGHE CITY (TW); DA-CHUNG CONTACT PROBES ENTERPRISE CO., LTD., CHUNG-HO CITY (TW)

(21) Appl. No.: 12/236,153

(22) Filed: Sep. 23, 2008

(51) Int. Cl. G01R 1/067

(52) U.S. Cl. 324/761

(57) ABSTRACT

A contact probe assembly, for placement within a probe receptacle for performing tests on an electrical device, includes the following elements. The hollow barrel has two openings at two opposite ends thereof, wherein the hollow barrel is adapted to be axially disposed within the probe receptacle. The first plunger is slidably disposed within one of the two openings at one end of the hollow barrel. The second plunger is slidably disposed within the other of the two openings at the opposite end of the hollow barrel. The resilient member is disposed within the hollow barrel and interconnected between the first plunger and second plunger, wherein the first plunger, the resilient member and the second plunger are formed as single one unitary member and made of the same electrically-conductive material.

### BACKGROUND

1. Field of Invention

The present invention relates to electrical contact probes. More particularly, the present invention relates to a spring-loaded contact probes used in electrical testing applications such as providing electrical contact between diagnostic or testing equipment and a device under test.

2. Description of Related Art

As illustrated in FIG. 1, a conventional spring-loaded contact probe assembly 100 for placement within a probe receptacle 109 for performing tests on an electrical device generally includes a barrel 102, an upper plunger 104, a lower plunger 106 and a spring 108 for biasing the reciprocating travel of the upper plunger 104 and lower plunger 106 in the barrel 102. The upper plunger 104 or lower plunger 106 is commonly biased outwardly a selected distance by the spring 108 and may be biased or depressed inwardly of the barrel 102, a selected distance, under force directed against the spring 108. The upper plunger 104 or lower plunger 106 generally includes a head or tip for contacting an electrical device 120 or a testing device 110.

In conventional devices, an electrical signal is routed through the upper plunger 104, the barrel 102, the lower plunger 106 and then into the electrical device 120 (as illustrated as the route 130). In order to enhance electrically-conductive interface between the (upper or lower) plunger and the barrel, a refractory metal is coated on an inner surface of the barrel 102. After repeated test cycles, it has been discovered that the refractory metal coating would be gradually worn out such that the electrical signal could be improperly transferred along the route 130.

### SUMMARY

It is therefore an objective of the present invention to provide an improved electrical contact probe.

In accordance with the foregoing and other objectives of the present invention, a contact probe assembly, for placement within a probe receptacle for performing tests on an electrical device, includes a hollow barrel, a first plunger, a second plunger and a resilient member. The hollow barrel has two openings at two opposite ends thereof, wherein the hollow barrel is adapted to be axially disposed within the probe receptacle. The first plunger is slidably disposed within one of the two openings at one end of the hollow barrel. The second plunger is slidably disposed within the other of the two openings at the opposite end of the hollow barrel. The resilient member is disposed within the hollow barrel and interconnected between the first plunger and second plunger, wherein the first plunger, the resilient member and the second plunger are formed as single one unitary member and made of the same electrically-conductive material.

In accordance with the foregoing and other objectives of the present invention, a contact probe, which is adapted to be axially disposed within a probe receptacle for performing tests on an electrical device, consisting essentially of a first plunger, a second plunger and a resilient member. The resilient member is interconnected between the first plunger and the second plunger, wherein the first plunger, the resilient member and the second plunger are formed as single one unitary member and made of the same electrically-conductive material.

In accordance with the foregoing and other objectives of the present invention, a contact probe assembly, for placement within a probe receptacle for performing tests on an electrical device, consisting essentially of a hollow barrel, a plunger and a resilient member. The hollow barrel has two openings at two opposite ends thereof, wherein the hollow barrel is adapted to be axially disposed within the probe receptacle. The plunger is slidably disposed within one of the two openings at one end of the hollow barrel. The resilient member is disposed within the hollow barrel and connected to the plunger, wherein the plunger and the resilient member are formed as single one unitary member and made of the same electrically-conductive material.

Thus, the present invention provides a spring-load contact probe with its plunger and resilient member formed as single one unitary member and made of the same electrically-conductive material, which results in an improved electrical-signal transmitting quality.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a conventional spring-loaded contact probe assembly; and

FIG. 2 illustrates a spring-loaded contact probe according to a first preferred embodiment of this invention;

FIG. 3 illustrates a spring-loaded contact probe according to a second preferred embodiment of this invention;

FIG. 4 illustrates a spring-loaded contact probe according to a third preferred embodiment of this invention;

FIG. 5 illustrates a spring-loaded contact probe according to a fourth preferred embodiment of this invention; and

FIGS. 6A-6D illustrate four types of resilient members according to embodiments of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

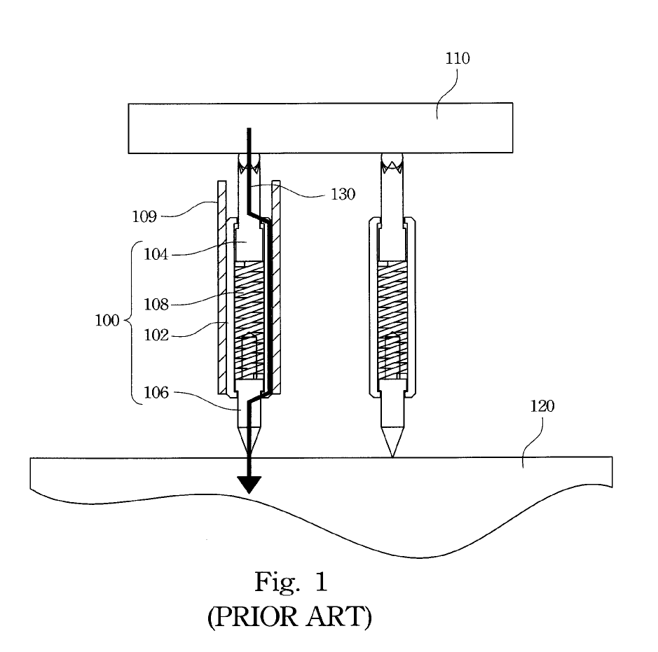

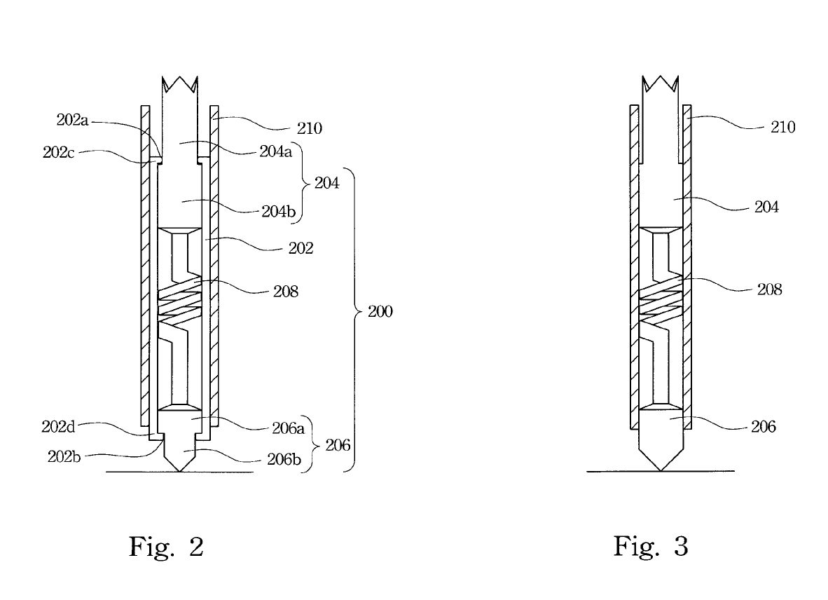

FIG. 2 illustrates a spring-loaded contact probe according to a first preferred embodiment of this invention. A contact probe assembly 200 for placement within a probe receptacle 210 for performing tests on an electrical device includes a hollow barrel 202, a plunger 204, a plunger 206 and a resilient member 208. The hollow barrel 202 has two openings (202a, 202b) at two opposite ends thereof. The hollow barrel 202 is adapted to be axially disposed within the probe receptacle 210. The plunger 204 is slidably disposed within the opening 202a of the hollow barrel 202. The plunger 206 is slidably disposed within the opening 202b of the hollow barrel 202. The resilient member 208 is disposed within the hollow barrel 202 and interconnected between the plunger 204 and the plunger 206. It should be noted that the plunger 204, the resilient member 208 and the plunger 206 are formed as single one unitary member, rather than separate members assembled within the hollow barrel 202. Thus, the plunger 204, the resilient member 208 and the plunger 206 are made of the same electrically-conductive material, i.e. carbon steel or beryllium cooper. In a test cycle, an electrical signal can be effectively routed mainly through a route of the plunger 204, the resilient member 208 and the plunger 206 since these three parts are actually one unitary member. The electrical signal may also be routed through the plunger 204, the barrel 202 and the plunger 206 as a secondary route (same as the route 130 illustrated in FIG. 1). Whatever the secondary route is effective, the major route is effective and more reliable to transfer the electrical signal (compared with the conventional spring-loaded contact probe assembly 100 as illustrated in FIG. 1).

The plunger 204 has a major portion 204b and a tip portion 204a both of a circular cross-section. The tip portion 204a has a relatively short radius and the major portion 204b has a relatively long radius. Similarly, the plunger 206 has a major portion 206a and a tip portion 206b both of a circular cross-section. The tip portion 206b has a relatively short radius and the major portion 206a has a relatively long radius.

Two opposite ends of the hollow barrel 202 include constricted sections (202c, 202d) to restrict the major portion 204b of the plunger 204 and the major portion 206a of the plunger 206 such that the major portion 204b and the major portion 206a slide within the hollow barrel 202. In this preferred embodiment, the resilient member 208 is formed as a circular helix with a constant radius. The resilient member 208 is of a relatively small cross-section compared to the plunger 204 and plunger 206.

FIG. 3 illustrates a spring-loaded contact probe according to a second preferred embodiment of this invention. Since the electrical signal is not necessarily routed through the plunger 204, the barrel 202 and the plunger 206 as illustrated in FIG. 2, the barrel 202 can be removed as illustrated in FIG. 3. In this preferred embodiment, the plunger 204, the resilient member 208 and the plunger 206 are also formed as single one unitary member and adapted to be axially disposed within the probe receptacle 210 without the barrel 202. Any design adapted to be assembled within the barrel 202, i.e. the plunger has a major portion with a relatively long radius and a tip portion with a relatively short radius, is not essential to the contact probe as illustrated in FIG. 3. The plunger 204, the resilient member 208 and the plunger 206 are made of the same electrically-conductive material, i.e. carbon steel or beryllium cooper.

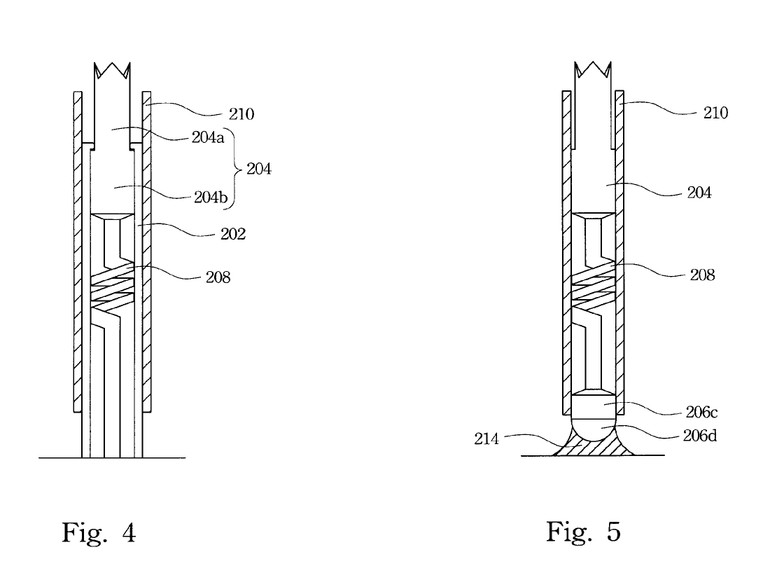

FIG. 4 illustrates a spring-loaded contact probe according to a third preferred embodiment of this invention. In this preferred embodiment, one of the two plungers (as illustrated in FIG. 4) is removed. The contact probe assembly for placement within a probe receptacle 210 for performing tests on an electrical device consists essentially of a hollow barrel 202, a plunger 204 and a resilient member 208. The plunger 206's function is replaced by the hollow barrel 202. That is, an electrical signal is routed majorly through the plunger 204 and the hollow barrel 202 in a test cycle. The resilient member 208 is operable mainly for biasing the plunger 204.

FIG. 5 illustrates a spring-loaded contact probe according to a fourth preferred embodiment of this invention. The contact probe in this embodiment has a different type of plunger 206c compared with the plunger 206 as illustrated in FIG. 3. The plunger 206c is adapted to be connected with the device under test by a solder 214. That is, the plunger 206c has a hemispheric tip 206d to be soldered.

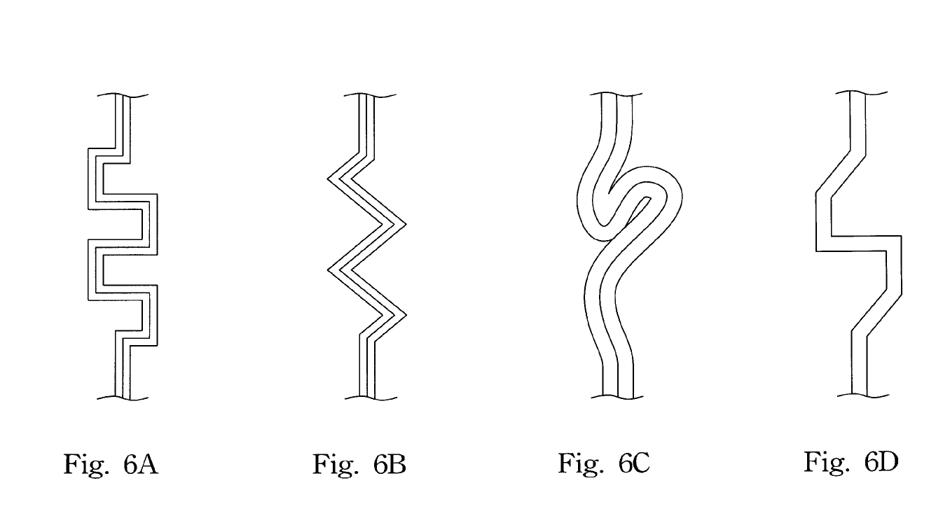

FIGS. 6A-6D illustrate four types of resilient members according to embodiments of this invention. In FIG. 6A, a resilient member consisting of continuous alternating [symbol] shapes is illustrated. In FIG. 6B, a resilient member is of a zigzag with a constant pitch. In FIG. 6C, a resilient member of an irregular shape is illustrated. FIG. 6D, a resilient member with a symmetric shape is illustrated.

According to discussed embodiments, the present invention provides a spring-load contact probe with its plunger and resilient member formed as single one unitary member and made of the same electrically-conductive material, which results in an improved electrical-signal transmitting quality.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A contact probe assembly for placement within a probe receptacle for performing tests on an electrical device, the contact probe assembly comprising:
a hollow barrel having two openings at two opposite ends thereof, wherein the hollow barrel is adapted to be axially disposed within the probe receptacle;
a first plunger slidably disposed within one of the two openings at one end of the hollow barrel;
a second plunger slidably disposed within the other of the two openings at the opposite end of the hollow barrel; and
a resilient member disposed within the hollow barrel and interconnected between the first plunger and second plunger, wherein the first plunger, the resilient member and the second plunger are formed as single one unitary member and made of the same electrically-conductive material.

2. The contact probe assembly of claim 1, wherein the same electrically-conductive material is carbon steel.

3. The contact probe assembly of claim 1, wherein the same electrically-conductive material is beryllium cooper.

4. The contact probe assembly of claim 1, wherein each of the two opposite ends of the hollow barrel comprises a constricted section to hold the first plunger, the resilient member and the second plunger within the hollow barrel.

5. The contact probe assembly of claim 1, wherein the resilient member is formed as a circular helix with a constant radius.

6. The contact probe assembly of claim 1, wherein the resilient member is formed as a zigzag with a constant pitch.

7. The contact probe assembly of claim 1, wherein the first plunger comprises a hemispheric tip.

8. A contact probe being adapted to be axially disposed within a probe receptacle directly for performing tests on an electrical device without a hollow barrel housing the contact probe, the contact probe consisting essentially of:
a first plunger and a second plunger; and
a resilient member interconnected between the first plunger and the second plunger, wherein the first plunger, the resilient member and the second plunger are formed as single one unitary member and made of the same electrically-conductive material.

9. The contact probe of claim 8, wherein the same electrically-conductive material is carbon steel.

10. The contact probe of claim 8, wherein the same electrically-conductive material is beryllium cooper.

11. The contact probe of claim 8, wherein the resilient member is formed as a circular helix with a constant radius.

12. The contact probe of claim 8, wherein the resilient member is formed as a zigzag with a constant pitch.

13. A contact probe assembly for placement within a probe receptacle for performing tests on an electrical device, the contact probe assembly being equipped with single one plunger, the contact probe assembly consisting essentially of:
a hollow barrel having two openings at two opposite ends thereof, wherein the hollow barrel is adapted to be axially disposed within the probe receptacle;
a plunger slidably disposed within one of the two openings at one end of the hollow barrel; and
a resilient member disposed within the hollow barrel and connected to the plunger, wherein the plunger and the resilient member are formed as single one unitary member and made of the same electrically-conductive material.

14. The contact probe assembly of claim 13, wherein the same electrically-conductive material is carbon steel.

15. The contact probe assembly of claim 13, wherein the same electrically-conductive material is beryllium cooper.

16. The contact probe assembly of claim 13, wherein each of the two opposite ends comprises a constricted section to hold the plunger and the resilient member within the hollow barrel.

17. The contact probe assembly of claim 13, wherein the resilient member is formed as a circular helix with a constant radius.

18. The contact probe assembly of claim 13, wherein the resilient member is formed as a zigzag with a constant pitch.
